(19) United States
(12) Patent Application Publication
(10) Pub. No.: US 2024/0347985 A1
(43) Pub. Date: Oct. 17, 2024

(54) Color coded alert system for an extensions cord, and related methods

(71) Applicant: Prime Wire & Cable, Inc., La Jolla, CA (US)

(72) Inventors: Jeff Millar-Sax, Los Angeles, CA (US); Kevin Baum, La Jolla, CA (US); Fred Chen, Ningbo (CN); Qing Chen, Ningbo (CN); Zhengwei Song, Ningbo (CN)

(21) Appl. No.: 17/114,269

(22) Filed: Dec. 7, 2020

(51) Int. Cl. H01R 13/717; G08B 5/36; G08B 21/02; H01R 13/66; H05B 45/20

(52) U.S. Cl. CPC H01R 13/7175; H01R 13/6675; H05B 45/20; G08B 5/36; G08B 21/02

(57) ABSTRACT

Disclosed is a power plug capable of indicating the current size, which can indicate the current size through an LED lamp. It is easy to understand the power plug connected to the real-time current size of the electrical equipment will improve the safety of electricity. A current display unit is set on the power socket itself. The current display unit is connected with a live wire plug and a zero wire plug respectively. The current display unit includes electrically connected: sampling module, the sampling module is connected with a live wire plug and a zero wire plug respectively, use to sample the current of electrical equipment connected to a power plug; the control module, the control unit and the sampling unit are connected, the control unit is also electrically connected with the display module; display module, display module includes several LED lights, the control module collects the current data according to the sampling module, control different LED lights to glow; power supply module, which is connected with control module and display module respectively, is used to supply power for control module and display module.

### CROSS-REFERENCE TO RELATED APPLICATIONS

Not applicable.

### STATEMENT REGARDING FEDERALLY SPONSORED RESEARCH OR DEVELOPMENT

Not applicable.

### THE NAMES OF THE PARTIES TO A JOINT RESEARCH AGREEMENT

Not applicable.

### REFERENCE TO AN APPENDIX SUBMITTED ON A COMPACT DISC AND INCORPORATED BY REFERENCE OF THE MATERIAL ON THE COMPACT DISC

Not applicable.

### STATEMENT REGARDING PRIOR DISCLOSURES BY THE INVENTOR OR A JOINT INVENTOR

Reserved for a later date, if necessary.

### BACKGROUND OF THE INVENTION

### Field of Invention

The disclosed subject matter is in the field of electronic components, and specifically, power plugs which can indicate current and alert a user to dangerous or problematic current levels.

### Background of the Invention

Electricity is a form of energy that is facilitated by the flow of electrons or current through a medium, generally a wire. Electricity is the most common mode by which energy is transmitted from a generator to an end user. Nearly all developed countries have an electrical grid of some type which is used to generate and distribute electricity. Electrical energy is often generated at a power plant using solar panels or a generator. Thereafter, the current and voltage are manipulated via a transformer and the energy is distributed via a network of transmission lines. The current and voltage may be stepped down or manipulated again thereafter and distributed to the end user. Up until the point at which electricity is delivered to the end user, the process is heavily controlled. Currents and voltages are maintained within specific ranges to conform to the hardware parameters of the components which the current passes through. In North America, wall sockets have a voltage of 60 from which the user devices draw current from according to their own device parameters via a power plug.

The power plug or receptacle is a device that the end user uses to connect a device to the electrical grid. The power plug or receptacle may feature a plurality of male and/or female electrical contacts. These contacts complete a circuit between the electrical grid and the electrical device allowing current to flow from the grid into the device and back into the grid. The power socket and the plug are different according to the country in the region, in terms of appearance, class, size and type. The power plug or receptacle used by different electrical appliances may also be different.

Power plugs or receptacles are often connected to different pieces of electrical equipment to provide power to them. Electrical equipment is designed and graded for different loads. By design some devices or components may draw more current than an intermediated device such as an extension cord is designed to carry. At this point, the intermediated device may be overloaded. Overloaded components are indicated by flickering, blinking, or dimming lights, tripped circuit breakers or blown fuses, warm or discolored wall plates, crackling, sizzling or buzzing sockets, burning odors coming from sockets or wall switches, or shocks coming from appliances or sockets. Overloaded components and circuits get very hot, potentially melting the circuit or causing fires if there is no circuit breaker in the circuit. At this point damage becomes hard to mitigate.

Currently, when the power plug or receptacle is connected to the high-power equipment, and the current draw is too large, there is a potential safety hazard. Further expanding the safety hazard is the fact that some devices do not have current detection capabilities. In order to ensure the safety of electricity, or to understand the real-time load of the equipment, there is a need for current detection and signaling on these devices. However, it is difficult to install the module of current detection on the equipment, and design changes need to be repeated for different devices. Because of the high cost and poor generality, Applicant proposes a power plug or receptacle which can indicate the current draw to the user.

### LISTING OF RELATED ART

US20030234729 to Shen discloses a, “Power extension cable with loading indication and warning.”
U.S. Pat. No. 7,605,594 to Blades discloses an, “Automated electrical wiring inspection system.”
US20100317222 to Tom discloses a, “Electrical power extension cord having continuous electrical current and ground monitor.”
U.S. Pat. No. 3,786,501 to Marnerakis discloses a, “Current monitoring system and Method.”
U.S. Pat. No. 1,399,695 to Dermarest discloses, “Electrical testing circuits.”
CN207394516U to Shimei discloses, “A kind of integral type ammeter light source with stent light-guiding pillar.”
CN108650729A to Xiao discloses, “A kind of single lamp dual control circuit of ammeter light pulse and pulse per second (PPS).”
JPH09318674A to Ishikawa discloses a, “Simplified photoelectric ammeter.”
JPH058469U to Shigenori discloses a, “Transmission line current optical measuring device.”
U.S. Pat. No. 8,085,517 to Weems discloses a, “Apparatus and method for ground fault detection and location in electrical systems.”
US20070013380A1 to Word discloses a, “Circuit breaker with integrated ammeter.”
U.S. Pat. No. 8,957,668 to Franke discloses a, “Integrated current sensor.”
WO2015186140A1 to Kumar discloses a, “Compact ammeter with integrated warning indicators.”
JP2017195162A to Arai discloses a, “Luminaire.”
U.S. Pat. No. 7,121,707 to Currie discloses a, “Illuminated electrical cords and outlets.”
U.S. Pat. No. 4,118,690 to Paynton discloses a, “Electrical hazard indicator.”
U.S. Pat. No. 4,318,578 to Ericson discloses a, “Electrical connector with ground fault detector.”
U.S. Pat. No. 6,053,765 to Eakins discloses a, “Electrical connector incorporating a light.”
US20080293290A1 to Ku discloses a, “Extension cord using LED as an indicator lamp.”
U.S. Pat. No. 9,361,770 to Murphy discloses a, “Electrical device current flow indicator.”
U.S. Pat. No. 5,207,594 to Olson discloses a, “Electrical power extension cord.”
WO2003067717A1 to Ohman discloses a, “Electrical extension cord with voltage indication.”
CA2039090C to Baines discloses a, “Illuminated extension cord.”
U.S. Pat. No. 8,834,198 to O'Rourke discloses a, “Electrical adaptor having a temperature indicator.”
U.S. Pat. No. 7,371,121 to Lee discloses a, “Multiple electrical outlet.”
U.S. Pat. No. 7,011,422 to Robertson discloses a, “Illuminated power strip and electrical outlet.”
US20190296503A1 to Gilliland discloses a, “Electrical cord having plugs with multi-functional light indicators.”
U.S. Pat. No. 7,086,892 to Tanacan discloses a, “Live circuit indicator for plugs and receptacles.”
US20060039136A1 to Probasco discloses a, “Lighted plug apparatus.”
U.S. Pat. No. 8,092,250 to Alami discloses a, “Electrical connection device with light indicator.”

### SUMMARY OF THE INVENTION

In view of the foregoing the object of this specification is to disclose a power plug or receptacle that addresses the problem of excessively large draws by indicating loads to users. To solve the above problems, the utility model provides a power plug or receptacle which can indicate the current size through the LED light. The power plug or receptacle capable of indicating the real-time current size of the electrical equipment will improve the safety of electricity for the end user by indicating the presence of overloaded circuits.

In one embodiment the system is an illuminated alarm power plug or receptacle with an integrated current detection transformer or ammeter. The extension cord plug or plugs may illuminate a different color depending on the current draw measured by the ammeter. Color coded current draws may notify a user if the attached device is drawing too much current.

In one embodiment, a green light may be associated with 0-13 Amps, an orange light may be associated with 13-15 Amps, and a red flashing light may be associated with 15+ Amps. The current measurements are designed and intended to be controlled at 5-10% accuracy.

The power plug or receptacle notifies users of quantified current draws and this capability increases component longevity by avoiding premature cord burnout. Burnout may occur when a power cord draws current beyond the cord's designed current draw limits. For instance, premature cord burnout may occur if a contractor is using a 15 Amp cord configuration at a site with 20 Amp temporary circuits. Premature cord burnout may be accelerated by the user using multiple tools on a multi-tap cord with the described circuit-cord configuration.

Like other electrical devices, the user may start by mating the alarm power cord to an electrical outlet and then mating a device's power cord to the power plug or receptacle. The power plug or receptacle self-inspects a plurality of components after two second of being powered. After initial self-inspection the cord may self-inspect intermittently at 11-minute intervals. In other embodiments, the cord may constantly monitor the load. The cord may send out the flashing red alarm signal if a component fails or if current draw is above 15 Amps.

It is also worth noting that the power plug or receptacle has been designed to comply with and actually perform new requirements for ground fault circuit interrupters (GFCI) with auto-monitoring functions. A GFCI is a personal protection device that protects people from a ground fault. A ground fault is an unintentional electrical path, for example, between a user of a power drill and the ground. The path for this electric current may start at a frayed cord of the power drill, pass through the user, and end at the ground.

In a preferred embodiment, the power plug or receptacle may feature the following components oriented in the following way. The plug may be embodied by a power plug or receptacle capable of indicating the current, including the power plug or receptacle body, which is at least connected to a live wire plug and a zero-wire plug. The live wire plug and the zero-wire plug can be connected to a power socket. The power socket itself is also provided with a current display unit, which is connected to the live wire plug and the zero wire plug respectively. The current display unit includes an electrically controlled connection. The sampling module is connected to the live wire plug and the zero wire plug respectively and used to sample the current of electrical equipment connected to a power plug or receptacle.

As part of the control module, the control unit is connected to the sampling unit, and the control unit is connected to the electronic control of the display module. The display module comprises several LED lights, and the control module controls different LED lights to emit light according to the current data collected by the sampling module.

The power supply module is connected to the control module and the display module respectively for supplying power to the control module and the display module. The sampling module includes an interface J1 connected to the live wire plug. Interface J1 connects with resistance R7 and then connects to interface J3, the interface J3 is connected to the live wire plug, and the interface J1 is also grounded after connecting resistances R8 and R9.

Further, the power supplying module comprises a rectifying diode D3 connected between interface J3 and resistance R7. Rectifier diode D3 is grounded at one end, the other end of rectifier diode D3 is sequentially connected to diode D2, resistor R5 and resistor R6 and then connected to 2 ports of stabilizer U2. The model of Voltage regulator U2 is 7533-1, between the resistor R6 and the two ports of stabilizer U2, also connecting the regulator D4 and capacitor C5 in parallel, the voltage regulator D4 and capacitance C5 are respectively grounded. The voltage regulator U2 is grounded at port 1, the voltage regulator U2 at port 3 connects to C4 and then grounding. The three ports of the voltage regulator U2 can output the power supply VCC. Interface J2 is also connected to one end of diode D2 after connecting resistor R4 and capacitor C3 in parallel.

Moreover, the control module includes controller U1, the model of which is PFC232. Port 1 of the controller U1 is connected to the power supply VCC. The 8 port of the controller U1 is grounded. Port 1 and port 8 of controller U1 are directly connected with capacitor C1. Port 5 of the controller U1 is connected to resistor R8 and resistor R9 of the sampling module and is grounded after connecting capacitor C2. The two ports of the controller U1 are sequentially connected to the resistor R3 and LED lamp Y of the display module and then connected to the power supply VCC. The six ports of the controller U1 are sequentially connected to the resistor R2 and LED lamp G of the display module and then connected to the power supply VCC. The 7 port of the controller U1 is connected to the resistor R1 and LED lamp R of the display module and then connected to the power supply VCC.

A point of novelty of the power plug or receptacle is its ability to indicate quantified current flows to the user. When the current collected by the sampling module is 0 A-13 A, the control module controls the lighting of the LED lamp G. When the current collected by the sampling module is 13 A-15 A, the control module controls the lighting of the LED lamp Y. When the current collected by the sampling module is greater than 15 A, the control module controls the lighting of the LED lamp R. It is worth noting that the LED lamp G is green, the LED lamp Y is yellow, and the LED lamp R is red. The power plug or receptacle body comprises a transparent housing through which the LED lamp of the current display unit can emit light. A ground wire plug connected to the power plug or receptacle body is also included.

The preferred embodiment relates to a power plug or receptacle which can indicate current. The current display unit connects the live wire plug and zero wire plug through the sampling module, that used to sample the current of electrical equipment connected to a power plug or receptacle. The current collected by the sampling module is obtained by the control module and the control module collects the current data according to the sampling module. The control display module for different LED lights to glow, when the current is normal, can be indicated by a green light. When the current level is in alert state, the yellow light can be used to indicate the current level needs to be addressed. When the current is too large, the red light can be used to indicate abnormal current. Different LED lights display different states of current, to ensure the safety of electricity, but it may also be convenient for the user to know the load of the electrical equipment. In addition, the body of the power plug or receptacle can be set into a transparent shell to facilitate the display of LED lights and improve the aesthetics of the power plug or receptacle.

### BRIEF DESCRIPTION OF THE SEVERAL VIEWS OF THE DRAWINGS

Other objectives of the disclosure will become apparent to those skilled in the art once the invention has been shown and described. The manner in which these objectives and other desirable characteristics can be obtained is explained in the following description and attached figures in which:

FIG. 1 is a block diagram of a current display unit of a power plug or receptacle which can indicate the current size of the utility model; and,

FIG. 2 is the circuit diagram of the current display unit of the power plug or receptacle which can indicate the current size of the utility model.

It is to be noted, however, that the appended figures illustrate only typical embodiments of this invention and are therefore not to be considered limiting of its scope, for the invention may admit to other equally effective embodiments that will be appreciated by those reasonably skilled in the relevant arts. Also, figures are not necessarily made to scale but are representative.

### DETAILED DESCRIPTION OF PREFERRED EMBODIMENTS

Disclosed is a clear and complete description of the technical scheme of the utility model, and the described embodiments are only part of the embodiments of this application and not all of them. Based on the embodiments in this application, all other embodiments obtained by ordinary technicians in this field without making creative work shall fall within the scope of protection in this application.

It should be noted that the terms “include” and “have” and any variations of them, the intent is to cover non-exclusive inclusions, for example, a system, product, or device that contains a series of steps or units need not be limited to those units that are clearly listed, instead, it may include other units that are not clearly listed or are inherent to these products or devices.

In the description of the utility model, the terms “installation”, “connecting” and “connecting” shall be understood in a broad sense unless otherwise specified and limited, for example, it can be mechanical connection or electrical connection, internal connection of two components, direct connection or indirect connection through intermediary. For ordinary technicians in this field, the specific meaning of the above terms can be understood according to the specific situation.

The preferred embodiment relates to a power plug or receptacle which can indicate the current. The system including a power plug or receptacle body, which is at least connected with a live wire plug and a zero-wire plug, a live wire plug and zero wire plug can be connected to a power outlet. The shape of the power plug or receptacle, the shape of the live wire plug, and the zero-wire plug can be set according to the national standard to design. Shape is not limited here according to national standards. According to the actual situation, the power plug or receptacle body may also be provided with a ground plug in some embodiments, and the current display unit is also set on the power socket body. The current display unit is connected to a live wire plug and a zero wire plug respectively.

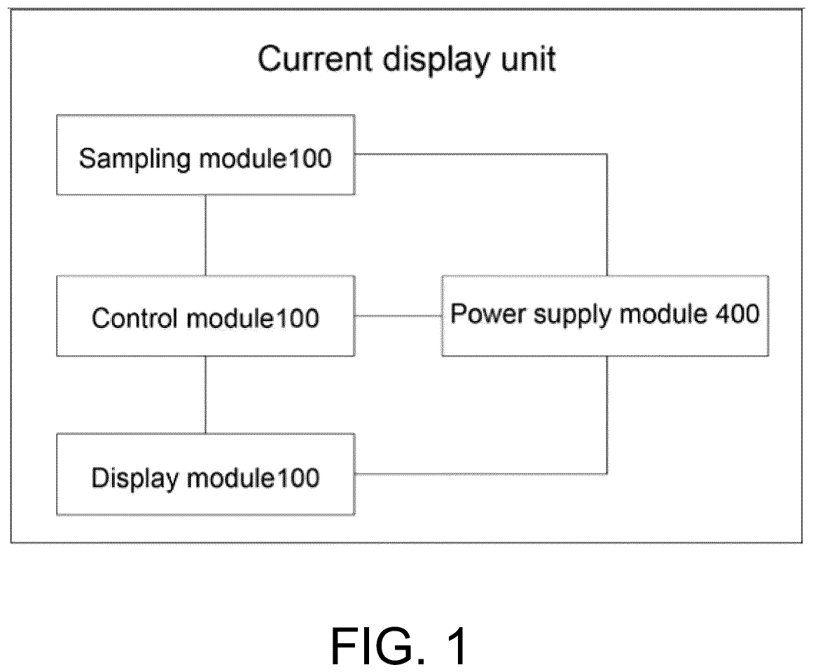

As shown in FIG. 1, in this embodiment, the current display unit includes electrically connected:
a sampling module 100, which is connected to the live wire plug and zero wire plug respectively, and is used for sampling the current of the electrical equipment connected to the power plug or receptacle;
a control module 200, which is connected to sampling unit 100 and electric control display module 300;
a display module 300 includes several LED lights, control module 200 controls different LED lights according to the current data collected by sampling module 100; and,
a power supply module 400, which is connected to the control module 200 and the display module 300 respectively and is used for power supply of the control module 200 and the display module 300.

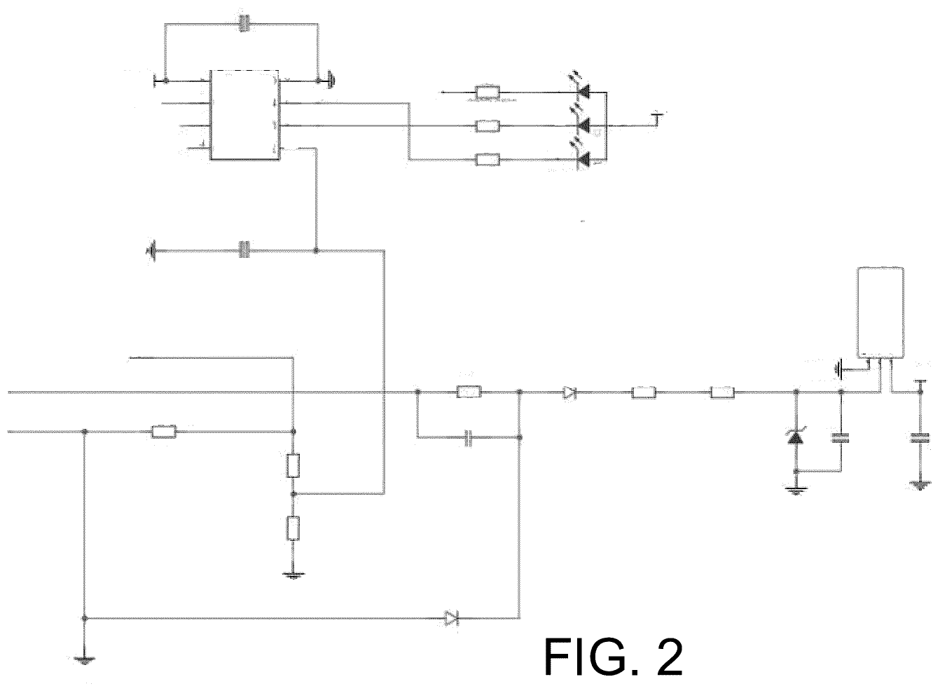

As shown in FIG. 2, specifically in this embodiment, the sampling module 100 includes an interface J1 connected to a live wire plug. Interface J1 connects resistor R7 to interface J3, which is connected to the live wire plug. Interface J1 is also grounded after connecting resistor R8 and resistor R9.

Specific to this embodiment, the power supply module 400 comprises a rectifying diode D3 connected between interface J3 and resistance R7, the rectifier diode D3 is grounded at one end, the other end of the rectifier diode D3 is connected to diode D2, resistor R5 and resistor R6 sequentially and then connected to port 2 of stabilizer U2. The Voltage regulator U2 is 7533-1. The resistor R6 is also connected to two ports of the stabilizer U2 with parallel connection of the stabilizer tube D4 and capacitance C5. The voltage regulator D4 and capacitance C5 are respectively grounded. The voltage regulator U2 is grounded at port 1. The voltage regulator U2 at port 3 connects to C4 and then grounding. The three ports of voltage regulator U2 can output power VCC. Interface J2 is also connected to one end of diode D2 after connecting resistor R4 and capacitor C3 in parallel. The input voltage of the live line is 220V or 125V (depending on the country), after rectifying diode rectification, it becomes 5V direct current, and then goes through the regulator tube to input voltage regulator, and the output VCC is 3.3V.

Further specific to this embodiment, the control module 200 includes the controller U1. The model of controller U1 is PFC232. Port 1 of controller U1 is connected to the power supply VCC, the 8 port of controller U1 is grounded. Port 1 and port 8 of controller U1 are directly connected with capacitor C1. Port 5 of controller U1 is connected to resistor R8 and resistor R9 of sampling module 100 and grounded after connecting capacitor C2. Port 2 of controller U1 is sequentially connected to resistor R3 of display module 300. LED lamp Y connects the power supply VCC. Port 6 of controller U1 is sequentially connected to resistor R2 of display module 300. LED lamp G is connected to power supply VCC, and port 7 of controller U1 is connected to resistor R1 of display module 300. LED lamp R is connected to power supply VCC.

In this embodiment, LED light G is green, LED light Y is yellow, and LED light R is red. When the current collected by the sampling module is 0 A-13 A, the control module controls the LED lamp G to light up. When the current collected by the sampling module is 13 A-15 A, the control module controls the LED lamp Y to light up. When the current collected by the sampling module is greater than 15 A, the control module controls the LED lamp R to light up. In a typical embodiment, the warning system is designed to show that the cord is operating at up to 80% load capacity (green light), “getting warmer” when operating at 80-100% capacity (yellow light) and when it gets over 100%, the red light starts flashing. These percentages are reflected in the preferred embodiment with 0-13 A, 13-15 A and over 15 A.

In another embodiment of the utility model, the LED lamp flicker can be controlled by output PWM signal of the control module, to realize the alarm, improve the display effect of the alarm, and make it easy for users to notice.

In an embodiment of the utility model, the LED lamp of the current display unit is located on the surface of the shell, and the light emitted by the LED lamp can be seen directly.

In another embodiment of the utility model, the power plug or receptacle body includes a transparent shell. The LED lamp of the current display unit can shine through the power plug or receptacle body, which is convenient for the display of LED lamp and may also improve the aesthetics of the power plug or receptacle.

The utility model has a power plug or receptacle capable of indicating the current size, which passes through a built-in current display unit. The current display unit connects the live wire plug and zero wire plug through the sampling module and is used for sampling the current of the electrical equipment connected with the power plug or receptacle. After the current collected by the sampling module is acquired by the control module, the control module collects the current data according to the sampling module prompting the control display module for different LED lights to glow. When the current is normal, it can be indicated by a green light. When the current level is in alert state, the yellow light can be used to indicate the current level needs to be addressed. When the current draw is too large, the red light can be used to indicate abnormal current. Different LED lights display different states of current, to ensure the safety of electricity. However, current flow signaling may be convenient for the user to know the load of the electrical equipment.

The above mentioned is only a better embodiment of the utility model and is not used to restrict the utility model. Any modification, equivalent replacement or improvement made within the technical scope of the utility model shall be included in the scope protected by the utility model.

Although the method and apparatus is described above in terms of various exemplary embodiments and implementations, it should be understood that the various features, aspects and functionality described in one or more of the individual embodiments are not limited in their applicability to the particular embodiment with which they are described, but instead might be applied, alone or in various combinations, to one or more of the other embodiments of the disclosed method and apparatus, whether or not such embodiments are described and whether or not such features are presented as being a part of a described embodiment. Thus, the breadth and scope of the claimed invention should not be limited by any of the above-described embodiments.

Terms and phrases used in this document, and variations thereof, unless otherwise expressly stated, should be construed as open-ended as opposed to limiting. As examples of the foregoing: the term “including” should be read as meaning “including, without limitation” or the like, the term “example” is used to provide exemplary instances of the item in discussion, not an exhaustive or limiting list thereof, the terms “a” or “an” should be read as meaning “at least one,” “one or more,” or the like, and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that might be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases might be absent. The use of the term “assembly” does not imply that the components or functionality described or claimed as part of the module are all configured in a common package. Indeed, any or all of the various components of a module, whether control logic or other components, might be combined in a single package or separately maintained and might further be distributed across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives might be implemented without confinement to the illustrated examples. For example, block diagrams and their accompanying description should not be construed as mandating a particular architecture or configuration.

All original claims submitted with this specification are incorporated by reference in their entirety as if fully set forth herein.

I claim:

1. A power plug which indicates the current size, including a power plug body, and the power plug body is at least connected with a live wire plug and a zero wire plug, the live wire plug and the zero wire plug can be connected with a power socket, its characteristic is that a current display unit is also arranged on the power socket body, the current display unit is connected with the live wire plug and the zero wire plug respectively, and the current display unit includes an electrically controlled connection:
a sampling module is respectively connected to the live wire plug and the zero wire plug for sampling the current of an electrical equipment connected to the power plug;
a control module, wherein a control unit is connected to a sampling unit, and the control unit is also connected with an electronic control of a display module;
The display module comprises a number of LED lights, and the control module controls different LED lights to emit light according to a current data collected by the sampling module;
a power supply module is connected to the control module and the display module respectively for supplying power to the control module and the display module.

2. The power plug capable of indicating the current of claim 1, wherein the sampling module includes an interface J1 connected to the live wire plug, interface J1 is connected to a resistor R7 and then connected to an interface J3 which is connected to the live wire plug, and the interface J1 is grounded after connecting a pair resistors R8 and R9.

3. The power plug capable of indicating the current of claim 2 wherein the power supply module comprises a rectifying diode D3 connected between interface J3 and resistance R7, one end of rectifier diode D3 is grounded, and the other end of rectifier diode D3 is sequentially connected to a diode D2, a resistor R5, a resistor R6 and then connected to two ports of a stabilizer U2, the stabilizer U2 being a 7533-1 type voltage regulator, the resistor R6 is also connected with two ports of the stabilizer U2 with parallel connection of a stabilizer tube D4 and capacitance C5, a voltage regulator D4 and capacitance C5 are respectively grounded, and the stabilizer U2 is grounded at port 1, the three ports of stabilizer U2 connects C4 and then grounding, the three ports of the voltage regulator U2 can output a power supply VCC, interface J2 is also connected to one end of diode D2 after connecting a resistor R4 and a capacitor C3 in parallel.

4. The power plug capable of indicating the current of claim 3 wherein the control module comprises a controller U1, the model of controller U1 is PFC232, port 1 of the controller U1 is connected to the power supply VCC, a port 8 of the controller U1 is grounded, a capacitor C1 is directly connected to port 1 of the controller U1 and port 8, a port 5 of the controller U1 is connected to resistor R8 and resistor R9 of the sampling module and is grounded after connecting a capacitor C2, the two ports of the controller U1 are sequentially connected to a resistor R3 and a LED lamp Y of the display module and then connected to the power supply VCC, the six ports of the controller U1 are sequentially connected to a resistor R2 and a LED lamp G of the display module and then connected to the power supply VCC, a port 7 of the controller U1 is connected to a resistor R1 and a LED lamp R of the display module and then connected to the power supply VCC.

5. The power plug capable of indicating the current of claim 4 wherein the current collected by the sampling module is 0 A-13 A, the control module controls the lighting of the LED lamp G, when the current collected by the sampling module is 13 A-15 A, the control module controls the lighting of the LED lamp Y, when the current collected by the sampling module is greater than 15 A, the control module controls the lighting of the LED lamp R.

6. The power plug capable of indicating the current of claim 4 wherein the LED lamp G is green, LED lamp Y is yellow and LED lamp R is red.

7. The power plug capable of indicating the current of claim 1, wherein the power plug body comprises a transparent shell, the LED lamp of the current display unit can emit light through the power plug body.

8. The power plug capable of indicating the current of claim 1, wherein the LED lamp of the current display unit is located on the surface of the shell.

9. The power plug capable of indicating the current of claim 1, wherein the plug includes a ground plug connected to the power plug body.
